(19) United States
(12) Patent Application Publication
(10) Pub. No.: US 2025/0057022 A1
(43) Pub. Date: Feb. 13, 2025

(54) WINDOW AND DISPLAY DEVICE INCLUDING THE SAME

(71) Applicant: Samsung Display Co., Ltd., Yongin-Si (KR)

(72) Inventors: SUNGWOO KIM, Yongin-si (KR); JAEHONG KIM, Yongin-si (KR); SOONRYONG PARK, Yongin-si (KR); JEONG SEOK LEE, Yongin-si (KR)

(21) Appl. No.: 18/663,080

(22) Filed: May 14, 2024

(30) Foreign Application Priority Data
Aug. 7, 2023 (KR) 10-2023-0103115

(51) Int. Cl. H10K 59/80

(52) U.S. Cl. CPC H10K 59/8791; H10K 59/873

(57) ABSTRACT

A window is disclosed that includes a base layer, a first layer disposed on the base layer, a second layer disposed on the first layer, and a third layer disposed on the second layer. Each of the first, second, and third layers include a first compound. When a ratio of an actual volume of a material to a total volume occupied by the material is defined as a packing density and the actual volume is defined by subtracting a void volume from the total volume, each of the first and third layers has a packing density of between about 75% to about 85% of a packing density of the second layer.

This U.S. non-provisional patent application claims priority under 35 U.S.C. § 119 of Korean Patent Application No. 10-2023-0103115, filed on Aug. 7, 2023, the contents of which are hereby incorporated by reference in its entirety.

### BACKGROUND

### 1. Field of Disclosure

The present disclosure relates to a window and a display device including the same.

### 2. Description of the Related Art

Display devices provide image information to users and are applied to various multimedia devices such as television sets, mobile phones, tablet computers, and game units. In recent years, various types of flexible display devices that are foldable or bendable have been developed. The shape of a flexible display device is able to be changed in various ways, e.g., by folding, rolling, or bending, making them is easier to carry.

A flexible display device includes a display panel and a window, which are foldable or bendable. However, the window of the flexible display device is likely to be deformed due to a folding or bending operation, or may be easily damaged by external impacts.

### SUMMARY

The present disclosure may provide a window that has low reflectance, excellent durability, and thin thickness with reduced difficulty of a manufacturing process thereof.

The present disclosure may provide a display device that has low reflectance, excellent durability, and thin thickness with reduced difficulty of a manufacturing process thereof.

An embodiment of a window includes a base layer, a first layer disposed on the base layer, a second layer disposed on the first layer, and a third layer disposed on the second layer. Each of the first, second, and third layers include a first compound, and when a ratio of an actual volume of a material to a total volume occupied by the material is defined as a packing density and the actual volume is defined by subtracting a void volume from the total volume, each of the first and third layers has a packing density of between about 75% to about 85% of a packing density of the second layer.

In an embodiment, the first compound includes one of silicon nitride, silicon oxide, aluminum oxide, aluminum oxynitride, silicon oxynitride, silicon aluminum oxynitride, niobium oxide, aluminum nitride, magnesium fluoride, magnesium oxide, titanium oxide, germanium oxide, magnesium aluminum oxide, barium fluoride, calcium fluoride, dysprosium fluoride, ytterbium fluoride, yttrium fluoride, cerium fluoride, tantalum oxide, hafnium oxide, zirconium oxide, yttrium oxide, molybdenum oxide, and a diamond-like carbon.

In an embodiment, the first compound includes silicon nitride.

In an embodiment, each of the first, second, and third layers consists of the first compound.

In an embodiment, the packing density of the first layer is substantially equal to the packing density of the third layer.

In an embodiment, the packing density of each of the first and third layers is about 80% of the packing density of the second layer.

In an embodiment, each of the first and third layers has a refractive index equal to or greater than about 1.78 and equal to or smaller than about 1.87 at a wavelength of about 550 nm, and the second layer has a refractive index equal to or greater than about 1.98 and equal to or smaller than about 2.15 at the wavelength of about 550 nm.

In an embodiment, the first and third layers have the same refractive index as each other at the wavelength of about 550 nm.

In an embodiment, the second layer is disposed directly on the first layer, and the third layer is disposed directly on the second layer.

In an embodiment, the first layer has a thickness equal to or greater than about 78 nm and equal to or smaller than about 94 nm, the second layer has a thickness equal to or greater than about 120 nm and equal to or smaller than about 146 nm, and the third layer has a thickness equal to or greater than about 15 nm and equal to or smaller than about 19 nm.

In an embodiment, the window further includes a fourth layer disposed on the third layer and including perfluoropolyether (PFPE).

In an embodiment, the fourth layer has a thickness equal to or greater than about 20 nm and equal to or smaller than about 30 nm.

In an embodiment, the window further includes a fifth layer disposed between the third layer and the fourth layer and having a refractive index equal to or greater than about 1.43 and equal to or smaller than about 1.52 at the wavelength of about 550 nm.

In an embodiment, the fifth layer includes a fifth-first layer disposed on the third layer and a fifth-second layer disposed between the fifth-first layer and the fourth layer.

In an embodiment, the fifth-first layer has a planar structure, and the fifth-second layer has a columnar structure.

In an embodiment, the window further includes a sixth layer disposed on the third layer, including the first compound, and having a substantially same packing density as the packing density of the second layer.

An embodiment of a display device includes a display module and a window disposed on the display module. The window includes a first layer disposed on the display module, a second layer disposed on the first layer, and a third layer disposed on the second layer. Each of the first, second, and third layers include a same compound, and when a ratio of an actual volume a material to a total volume occupied by the material is defined as a packing density and the actual volume is defined by subtracting a void volume from the total volume, each of the first and third layers has a packing density of between about 75% to about 85% of a packing density of the second layer.

In an embodiment, the display module includes a base substrate, a circuit layer disposed on the base substrate, a light emitting element layer including a light emitting element and disposed on the circuit layer, and an anti-reflective layer including a color filter overlapping the light emitting element and disposed on the light emitting element layer.

In an embodiment, the display device further includes a fourth layer disposed on the third layer and including perfluoropolyether (PFPE).

In an embodiment, the upper surface of the fourth layer defines an outermost surface of the window.

According to the above, since the window includes a plurality of layers disposed on the base layer and including a predetermined material, the window has low reflectance, excellent durability, and thin thickness, and thus, the difficulty of manufacturing process thereof is reduced. Accordingly, the display device including the window also has low reflectance, excellent durability, and thin thickness, and the difficulty of manufacturing process thereof is reduced.

### BRIEF DESCRIPTION OF THE DRAWINGS

The above and other advantages of the present disclosure will become readily apparent by reference to the following detailed description when considered in conjunction with the accompanying drawings wherein:

FIG. 1A is an assembled perspective view of a display device according to an embodiment of the present disclosure;

FIG. 1B is an exploded perspective view of a display device according to an embodiment of the present disclosure;

FIG. 2 is a cross-sectional view of a display device according to an embodiment of the present disclosure;

FIG. 3 is a cross-sectional view of a portion of a display module according to an embodiment of the present disclosure;

FIG. 4 is a cross-sectional view of a window according to an embodiment of the present disclosure;

FIG. 5 is a cross-sectional view of a window according to an embodiment of the present disclosure; and

FIG. 6 is a cross-sectional view of a window according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “comprise” and “include” as well as their variations such as “including”, when used in this specification, specify the presence of stated features, integers, steps, operations, elements, or components, but do not preclude the presence or addition of one or more other features, integers, steps, operations, elements, components, or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

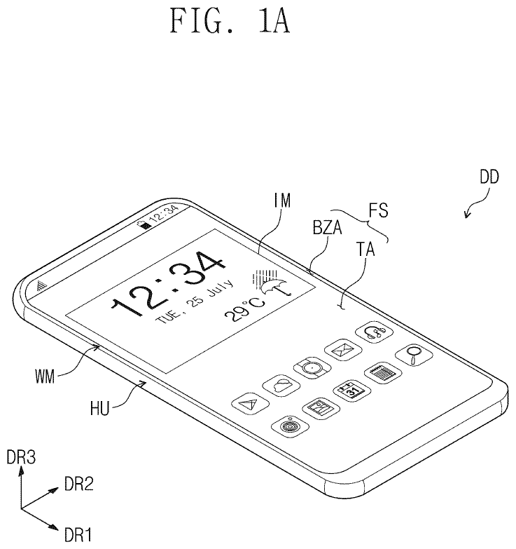

FIG. 1A is an assembled perspective view of a display device DD according to an embodiment of the present disclosure. FIG. 1B is an exploded perspective view of the display device DD according to an embodiment of the present disclosure.

Referring to FIGS. 1A and 1B, the display device DD may be activated in response to electrical signals. The display device DD may display an image IM and may sense an external input. The display device DD may be applied to various embodiments. For example, the display device DD may be applied to a tablet computer, a notebook computer, a computer, or a smart television. In the present embodiment, a smartphone will be described as a representative example of the display device DD.

The display device DD may display the image IM through a display surface FS, which is substantially parallel to each of a first direction DR1 and a second direction DR2, toward a third direction DR3. The display surface FS through which the image IM is displayed may correspond to a front surface of the display device DD and a front surface FS of a window WM. Hereinafter, the display surface and the front surface of the display device DD and the front surface of the window WM are referred to with the same character FS. The image IM may include a video as well as a still image. FIG. 1A shows a clock widget and application icons as a representative example of the image IM.

In the present embodiment, front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3. A separation distance in the third direction DR3 between the front surface and the rear surface of the each member may correspond to a thickness in the third direction DR3 of the each member. Directions indicated by the first, second, and third directions DR1, DR2, and DR3 are relative to each other, and thus, the directions indicated by the first, second, and third directions DR1, DR2, and DR3 may be changed to other directions. In the following descriptions, the expression “when viewed in a plane or in a plane” may mean a state of being viewed in the third direction DR3.

The display device DD may sense a user input applied thereto from the outside. The user input may include inputs of various forms, such as a part of a user's body, light, heat, or pressure. The user input may be provided in various ways. The display device DD may sense the user input applied to a side surface or a rear surface of the display device DD according to a structure of the display device DD, and the present disclosure should not be limited thereto or thereby.

Referring to FIGS. 1A and 1B, the display device DD may include the window WM, a display module DM, and an external case HU. In the present embodiment, the window WM and the external case HU may be coupled to each other to provide an appearance of the display device DD. In the present embodiment, the external case HU, the display module DM, and the window WM may be sequentially stacked in the third direction DR3.

The window WM may include an optically transparent material. The window WM may include an insulating panel. For example, the window WM may include a glass material, a plastic material, or a combination thereof.

The front surface FS of the window WM may define the front surface of the display device DD as described above. A transmissive area TA may be an optically transparent area. For example, the transmissive area TA may be an area having a visible light transmittance of about 90% or more.

A bezel area BZA may be an area having a relatively lower transmittance as compared with the transmissive area TA. The bezel area BZA may define a shape of the transmissive area TA. The bezel area BZA may be disposed adjacent to the transmissive area TA and may surround the transmissive area TA.

The bezel area BZA may have a predetermined color. The bezel area BZA may cover a peripheral area NAA of the display module DM to prevent the peripheral area NAA from being viewed from the outside. However, this is merely an example, and the bezel area BZA may be omitted from the window WM according to the embodiment of the present disclosure.

The display module DM may display the image IM and may sense the external input. The image IM may be displayed through a front surface IS of the display module DM. The front surface IS of the display module DM may include an active area AA and the peripheral area NAA. The active area AA may be an area that is activated in response to electrical signals.

In the present embodiment, the active area AA may be an area where the image IM is displayed and the external input is be sensed. The transmissive area TA may overlap at least the active area AA. For example, the transmissive area TA may overlap an entire surface or at least a portion of the active area AA. Accordingly, a user may view the image IM or may provide the external input through the transmissive area TA, however, this is merely an example. According to an embodiment, an area through which the image IM is displayed and an area through which the external input is sensed may be separated from each other in the active area AA, and they should not be limited to a particular embodiment.

The peripheral area NAA may be covered by the bezel area BZA. The peripheral area NAA may be disposed adjacent to the active area AA. The peripheral area NAA may surround the active area AA. A driving circuit or a driving line to drive the active area AA may be disposed in the peripheral area NAA.

The display module DM may include a display panel and a sensor layer. The image IM may be substantially displayed through the display panel, and the external input may be substantially sensed by the sensor layer. As the display module DM includes both the display panel and the sensor layer, the display module DM may display the image IM and may substantially simultaneously sense the external input. This will be described in detail later.

The display device DD may further include a driving circuit. The driving circuit may include a flexible circuit board and a main circuit board. The flexible circuit board may be electrically connected to the display module DM. The flexible circuit board may connect the display module DM to the main circuit board, however, this is merely an example. According to an embodiment, the flexible circuit board may not be connected to the main circuit board, and the flexible circuit board may be a rigid substrate.

The flexible circuit board may be connected to pads of the display module DM, which are disposed in the peripheral area NAA. The flexible circuit board may provide electrical signals to the display module DM to drive the display module DM. The electrical signals may be generated by the flexible circuit board or the main circuit board. The main circuit board may include various driving circuits to drive the display module DM or a connector to provide a power. The main circuit board may be connected to the display module DM through the flexible circuit board.

FIG. 1B shows an unfolded state of the display module DM as a representative example, however, at least a portion of the display module DM may be bent. In the present embodiment, a portion of the display module DM may be bent toward a rear surface of the display module DM, and the portion that is bent toward the rear surface may be a portion connected to the main circuit board. Accordingly, the main circuit board may be assembled while overlapping the rear surface of the display module DM.

The external case HU may be coupled to the window WM to define the appearance of the display device DD. The external case HU may provide a predetermined inner space. The display module DM may be accommodated in the inner space.

The external case HU may have a material with a relatively high rigidity. For example, the external case HU may include a glass, plastic, or metal material or a plurality of frames or plates or combinations thereof. The external case HU may stably protect the components of the display device DD, which are accommodated in the inner space, from external impacts.

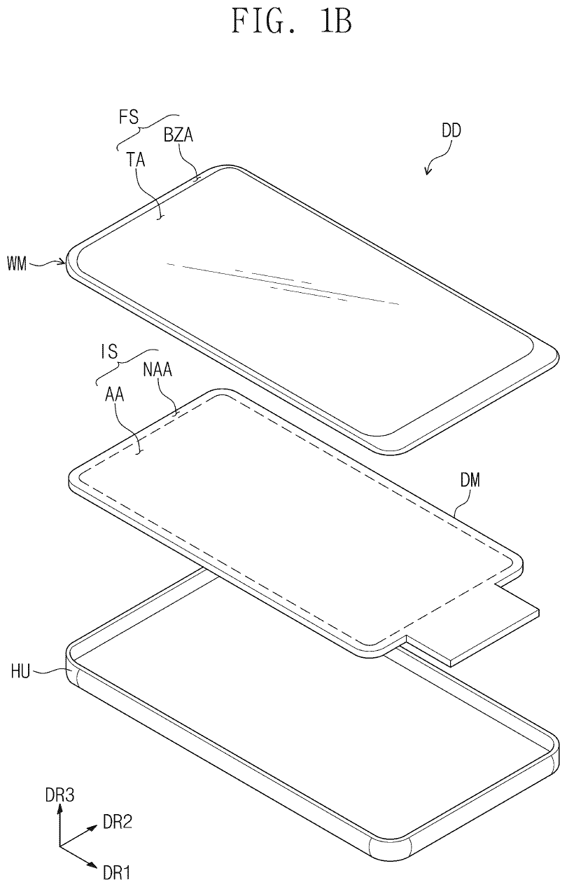

FIG. 2 is a cross-sectional view of the display device DD according to an embodiment of the present disclosure.

Referring to FIG. 2, the display device DD may include the display module DM and the window WM. The display module DM may be coupled with the window WM by an adhesive layer AD. The display module DM of the display device DD may include the display panel 100, the sensor layer 200, and an anti-reflective layer 300. Among layers of the display module DM, the anti-reflective layer 300 may be coupled with the window WM by the adhesive layer AD.

The display panel 100 may have a configuration that substantially generates the image. The display panel 100 may be a light emitting type display panel. For example, the display panel 100 may be an organic light emitting display panel, an inorganic light emitting display panel, a micro-LED display panel, or a nano-LED display panel. The display panel 100 may be referred to as a display layer.

The display panel 100 may include a base substrate 110, a circuit layer 120, a light emitting element layer 130, and an encapsulation layer 140.

The base substrate 110 may be a member that provides a base surface on which the circuit layer 120 is disposed. The base substrate 110 may be a rigid substrate or a flexible substrate that is bendable, foldable, or rollable. The base substrate 110 may be a glass substrate, a metal substrate, or a polymer substrate, however, it should not be limited thereto or thereby. According to an embodiment, the base substrate 110 may be an inorganic layer, an organic layer, or a composite material layer.

The base substrate 110 may have a multi-layer structure. For instance, the base substrate 110 may include a first synthetic resin layer, an inorganic layer having a single-layer or multi-layer structure, and a second synthetic resin layer disposed on the inorganic layer. Each of the first and second synthetic resin layers may include a polyimide-based resin, however, it should not be particularly limited.

The circuit layer 120 may be disposed on the base substrate 110. The circuit layer 120 may include an insulating layer, a semiconductor pattern, a conductive pattern, and a signal line.

The light emitting element layer 130 may be disposed on the circuit layer 120. The light emitting element layer 130 may include a light emitting element. As an example, the light emitting element may include an organic light emitting material, an inorganic light emitting material, an organic-inorganic light emitting material, a quantum dot, a quantum rod, a micro-LED, or a nano-LED.

The encapsulation layer 140 may be disposed on the light emitting element layer 130. The encapsulation layer 140 may protect the light emitting element layer 130 from moisture, oxygen, and a foreign substance such as dust particles. The encapsulation layer 140 may include at least one inorganic layer. The encapsulation layer 140 may include a stack structure of inorganic layer/organic layer/inorganic layer.

The sensor layer 200 may be disposed on the display panel 100. The sensor layer 200 may sense the external input applied thereto from the outside. The external input may be the user input. The user input may include inputs of various forms, such as a part of the user's body, light, heat, pen, or pressure.

The sensor layer 200 may be formed on the display panel 100 through successive processes. In this case, the sensor layer 200 may be disposed directly on the display panel 100. In the present disclosure, the expression “The sensor layer 200 is disposed directly on the display panel 100.” means that no intervening elements are present between the sensor layer 200 and the display panel 100. That is, a separate adhesive member may not be disposed between the sensor layer 200 and the display panel 100.

The anti-reflective layer 300 may be disposed directly on the sensor layer 200. The anti-reflective layer 300 may reduce a reflectance with respect to an external light incident to the display device DD from the outside. The anti-reflective layer 300 may be formed on the sensor layer 200 through successive processes. The anti-reflective layer 300 may include color filters. The color filters may be arranged in a predetermined way. The arrangement of the color filters may be determined by taking into account colors of lights emitted from pixels included in the display panel 100. In addition, the anti-reflective layer 300 may further include a black matrix adjacent to the color filters. The anti-reflective layer 300 will be described in detail later.

According to an embodiment, the sensor layer 200 may be omitted. In this case, the anti-reflective layer 300 may be disposed directly on the display panel 100. According to an embodiment, positions of the sensor layer 200 and the anti-reflective layer 300 may be changed with each other.

Although not shown in figures, according to an embodiment, the display device DD may further include an optical layer disposed on the anti-reflective layer 300. As an example, the optical layer may be formed on the anti-reflective layer 300 through successive processes. The optical layer may control a direction of a light incident from the display panel 100 to improve a front luminance of the display device DD. As an example, the optical layer may include an organic insulating layer through which openings are defined to respectively correspond to light emitting areas of the pixels included in the display panel 100 and a high refractive index layer covering the organic insulating layer and filled in the openings. The high refractive index layer may have a refractive index higher than that of the organic insulating layer.

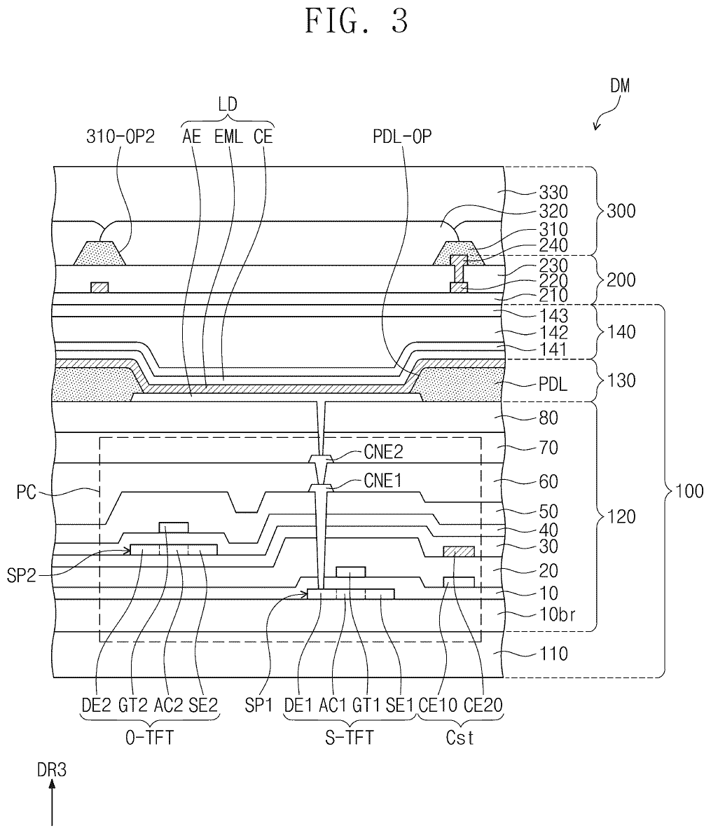

The window WM may provide the front surface of the display device DD. The window WM may include a glass film or a synthetic resin film as its base film. The window WM may further include functional layers such as an anti-reflective layer or an anti-fingerprint layer. The functional layers included in the window WM will be described later with reference to FIGS. 4 to 6. Although not shown in figures, the window WM may further include a bezel pattern overlapping the bezel area BZA (refer to FIG. 1B).

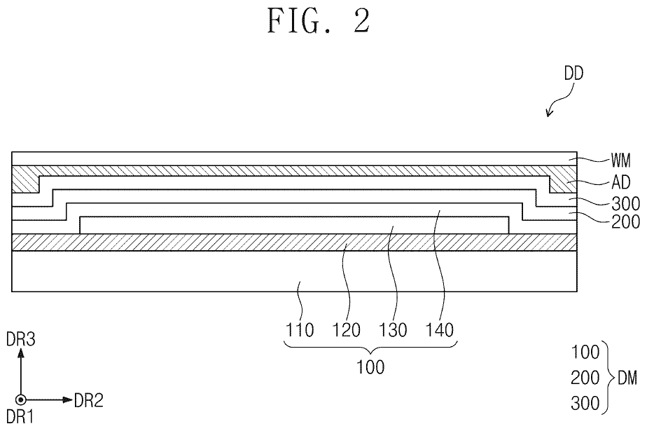

FIG. 3 is a cross-sectional view of a portion of the display module DM according to an embodiment of the present disclosure. FIG. 3 shows a cross-section of a portion of one light emitting element LD and a portion of a pixel circuit PC included in the display module DM. Hereinafter, components of the display module DM will be described in detail with reference to FIG. 3.

The display panel 100 included in the display module DM may include the base substrate 110. The base substrate 110 may be a member that provides a base surface on which the circuit layer 120 is disposed. The base substrate 110 may be a glass substrate, a metal substrate, a plastic substrate, or a silicon substrate, however, it should not be limited thereto or thereby. According to an embodiment, the base substrate 110 may be an inorganic layer, an organic layer, or a composite material layer.

A buffer layer 10br may be disposed on the base substrate 110. The buffer layer 10br may prevent metal atoms or impurities from being diffused upward to a first semiconductor pattern SP1 from the base substrate 110. The first semiconductor pattern SP1 may include a channel area AC1 of a silicon transistor S-TFT. The buffer layer 10br may control a rate of heat supply during a crystallization process to form the first semiconductor pattern SP1 so that the first semiconductor pattern SP1 may be uniformly formed.

The first semiconductor pattern SP1 may be disposed on the buffer layer 10br. The first semiconductor pattern SP1 may include a silicon semiconductor. As an example, the silicon semiconductor may include amorphous silicon, polycrystalline silicon, or crystalline silicon. For example, the first semiconductor pattern SP1 may include low temperature polycrystalline silicon.

FIG. 3 shows only a portion of the first semiconductor pattern SP1 disposed on the buffer layer 10br, and the first semiconductor pattern SP1 may be further disposed in other areas. The first semiconductor pattern SP1 may be arranged with a specific rule over the pixels. The first semiconductor pattern SP1 may have different electrical properties depending on whether it is doped or not or whether it is doped with an N-type dopant or a P-type dopant. The first semiconductor pattern SP1 may include a first region having a relatively high conductivity and a second region having a relatively low conductivity. The first region may be doped with the N-type dopant or the P-type dopant. A P-type transistor may include a region doped with the P-type dopant, and an N-type transistor may include a region doped with the N-type dopant. The second region may be a non-doped region or a region doped at a concentration lower than that of the first region.

The first region may have a conductivity greater than that of the second region and may substantially serve as an electrode or signal line. The second region may substantially correspond to an active area (or a channel) of the transistor. In other words, a portion of the first semiconductor pattern SP1 may be the active area of the transistor, another portion of the first semiconductor pattern SP1 may be a source or a drain of the transistor, and the other portion of the first semiconductor pattern SP1 may be a connection electrode or a connection signal line.

A source area SE1 (or a source), the channel area AC1 (or a channel), and a drain area DE1 (or a drain) of the silicon transistor S-TFT may be formed from the first semiconductor pattern SP1. The source area SE1 and the drain area DE1 may extend in opposite directions to each other from the channel area AC1 in a cross-section.

Although not shown in figures, a rear surface metal layer may be disposed under each of the silicon transistor S-TFT and an oxide transistor O-TFT. The rear surface metal layer may overlap the pixel circuit PC and may prevent the external light from reaching the pixel circuit PC. The rear surface metal layer may be disposed between the base substrate 110 and the buffer layer 10br. According to an embodiment, the rear surface metal layer may be disposed between a second insulating layer 20 and a third insulating layer 30. The rear surface metal layer may include a reflective metal. As an example, the rear surface metal layer may include silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), p+ doped amorphous silicon, or the like. The rear surface metal layer may be connected to an electrode or a wire and may receive a constant voltage or a signal from the electrode or wire. According to an embodiment, the rear surface metal layer may be a floating electrode that is isolated from other electrodes or wire. According to an embodiment, an inorganic barrier layer may be further disposed between the base substrate 110 and the buffer layer 10br.

A first insulating layer 10 may be disposed on the buffer layer 10br. The first insulating layer 10 may commonly overlap the pixels and may cover the first semiconductor pattern SP1. The first insulating layer 10 may be an inorganic layer or an organic layer and may have a single-layer or multi-layer structure. The first insulating layer 10 may include at least one of aluminum oxide, titanium oxide, silicon oxide, silicon nitride, silicon oxynitride, zirconium oxide, and hafnium oxide. In the present embodiment, the first insulating layer 10 may have a single-layer structure of a silicon oxide layer. Not only the first insulating layer 10, but also an insulating layer of the circuit layer 120 described later may be an inorganic layer or an organic layer and may have a single-layer or multi-layer structure. The inorganic layer may include at least one of the above-mentioned materials, however, it should not be limited thereto or thereby.

A gate GT1 of the silicon transistor S-TFT may be disposed on the first insulating layer 10. The gate GT1 may be a portion of a metal pattern. The gate GT1 may overlap the channel area AC1. The gate GT1 may be used as a mask in a process of doping the first semiconductor pattern SP1. The gate GT1 may include titanium (Ti), silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like, however, it should not be particularly limited.

The second insulating layer 20 may be disposed on the first insulating layer 10 and may cover the gate GT1. The third insulating layer 30 may be disposed on the second insulating layer 20. A second electrode CE20 of a storage capacitor Cst may be disposed between the second insulating layer 20 and the third insulating layer 30. In addition, a first electrode CE10 of the storage capacitor Cst may be disposed between the first insulating layer 10 and the second insulating layer 20.

A second semiconductor pattern SP2 may be disposed on the third insulating layer 30. The second semiconductor pattern SP2 may include a channel area AC2 of the oxide transistor O-TFT described later. The second semiconductor pattern SP2 may include an oxide semiconductor. The second semiconductor pattern SP2 may include a transparent conductive oxide (TCO), such as indium tin oxide (ITO), indium zinc oxide (IZO), indium gallium zinc oxide (IGZO), zinc oxide (ZnO), or indium oxide (In₂O₃).

The oxide semiconductor may include a plurality of areas distinguished from each other depending on whether the transparent conductive oxide is reduced or not. The area (hereinafter, referred to as a “reduced area”) in which the transparent conductive oxide is reduced has a conductivity greater than that of the area (hereinafter, referred to as a “non-reduced area”) in which the transparent conductive oxide is not reduced. The reduced area may substantially act as a source/drain of a transistor or a signal line. The non-reduced area may substantially correspond to a semiconductor area (or an active area or a channel) of the transistor. In other words, a portion of the second semiconductor pattern SP2 may be a semiconductor area of a transistor, another portion of the second semiconductor pattern SP2 may be source/drain areas of the transistor, and the other portion of the second semiconductor pattern SP2 may be a signal transmission area.

A source area SE2 (or a source), the channel area AC2 (or a channel), and a drain area DE2 (or a drain) of the oxide transistor O-TFT may be formed from the second semiconductor pattern SP2. The source area SE2 and the drain area DE2 may extend in opposite directions to each other from the channel area AC2 in a cross-section.

A fourth insulating layer 40 may be disposed on the third insulating layer 30. The fourth insulating layer 40 may commonly overlap the pixels and may cover the second semiconductor pattern SP2. Although not shown in figures, the fourth insulating layer 40 may be an insulating pattern that overlaps a gate GT2 of the oxide transistor O-TFT and exposes the source area SE2 and the drain area DE2 of the oxide transistor O-TFT.

The gate GT2 of the oxide transistor O-TFT may be disposed on the fourth insulating layer 40. The gate GT2 of the oxide transistor O-TFT may be a portion of a metal pattern. The gate GT2 of the oxide transistor O-TFT may overlap the channel area AC2.

A fifth insulating layer 50 may be disposed on the fourth insulating layer 40 and may cover the gate GT2. A first connection electrode CNE1 may be disposed on the fifth insulating layer 50. The first connection electrode CNE1 may be connected to the drain area DE1 of the silicon transistor S-TFT via a contact hole defined through the first, second, third, fourth, and fifth insulating layers 10, 20, 30, 40, and 50.

A sixth insulating layer 60 may be disposed on the fifth insulating layer 50. A second connection electrode CNE2 may be disposed on the sixth insulating layer 60. The second connection electrode CNE2 may be connected to the first connection electrode CNE1 via a contact hole defined through the sixth insulating layer 60. A seventh insulating layer 70 may be disposed on the sixth insulating layer 60 and may cover the second connection electrode CNE2. An eighth insulating layer 80 may be disposed on the seventh insulating layer 70.

Each of the sixth insulating layer 60, the seventh insulating layer 70, and the eighth insulating layer 80 may be an organic layer. As an example, each of the sixth insulating layer 60, the seventh insulating layer 70, and the eighth insulating layer 80 may include a general-purpose polymer such as benzocyclobutene (BCB), polyimide, hexamethyldisiloxane (HMDSO), polymethylmethacrylate (PMMA), or polystyrene (PS), a polymer derivative having a phenolic group, an acrylic-based polymer, an imide-based polymer, an aryl ether-based polymer, an amide-based polymer, a fluorine-based polymer, a p-xylene-based polymer, a vinyl alcohol-based polymer, or blends thereof.

The light emitting layer 130 may disposed on the circuit layer 120. The light emitting layer 130 may include a light emitting element LD and a pixel definition layer PDL.

The light emitting element LD may include a first electrode AE (or a pixel electrode), a light emitting layer EML, and a second electrode CE (or a common electrode). Each of the light emitting layer EML and the second electrode CE may be commonly formed over the pixels.

The first electrode AE of the light emitting element LD may be disposed on the eighth insulating layer 80. The first electrode AE of the light emitting element LD may be a semi-transmissive electrode, a transmissive electrode, or a reflective electrode. According to an embodiment, the first electrode AE of the light emitting element LD may include a reflective layer formed of Ag, Mg, Al, Pt, Pd, Au, Ni, Nd, Ir, Cr, or compounds thereof and a transparent or semi-transparent electrode layer formed on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO), indium oxide (In₂O₃), and aluminum-doped zinc oxide (AZO). For instance, the first electrode AE of the light emitting element LD may have a stack structure of ITO/Ag/ITO.

The pixel definition layer PDL may be disposed on the eighth insulating layer 80. The pixel definition layer PDL may have a light absorbing property. For example, the pixel definition layer PDL may have a black color. The pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light blocking pattern having a light blocking property.

The pixel definition layer PDL may cover a portion of the first electrode AE of the light emitting element LD. As an example, the pixel definition layer PDL may be provided with an opening PDL-OP defined therethrough to expose a portion of the first electrode AE of the light emitting element LD. The pixel definition layer PDL may increase a distance between an edge of the first electrode AE and the second electrode CE of the light emitting element LD. Accordingly, an occurrence of an arc on the edge of the first electrode AE may be prevented by the pixel definition layer PDL.

Although not shown in figures, a hole control layer may be disposed between the first electrode AE and the light emitting layer EML. The hole control layer may include a hole transport layer and may further include a hole injection layer. An electron control layer may be disposed between the light emitting layer EML and the second electrode CE. The electron control layer may include an electron transport layer and may further include an electron injection layer. The hole control layer and the electron control layer may be commonly formed over the plural pixels using an open mask.

The encapsulation layer 140 may be disposed on the light emitting element layer 130. The encapsulation layer 140 may include an inorganic layer 141, an organic layer 142, and an inorganic layer 143, which are sequentially stacked, however, layers included in the encapsulation layer 140 should not be limited thereto or thereby.

The inorganic layers 141 and 143 may protect the light emitting element layer 130 from moisture and oxygen, and the organic layer 142 may protect the light emitting element layer 130 from a foreign substance such as dust particles. The inorganic layers 141 and 143 may include a silicon nitride layer, a silicon oxynitride layer, a silicon oxide layer, a titanium oxide layer, or an aluminum oxide layer. The organic layer 142 may include an acrylic-based organic layer, however, it should not be limited thereto or thereby.

The sensor layer 200 may be disposed on the display panel 100. The sensor layer 200 may be referred to as a sensor, an input sensing layer, or an input sensing panel. The sensor layer 200 may include a sensor base layer 210, a first conductive layer 220, a sensing insulating layer 230, and a second conductive layer 240.

The sensor base layer 210 may be disposed directly on the display panel 100. The sensor base layer 210 may be an inorganic layer including at least one of silicon nitride, silicon oxynitride, and silicon oxide. According to an embodiment, the sensor base layer 210 may be an organic layer including an epoxy resin, an acrylic resin, or an imide-based resin. The sensor base layer 210 may have a single-layer structure or a multi-layer structure of layers stacked in the third direction DR3.

Each of the first conductive layer 220 and the second conductive layer 240 may have a single-layer structure or a multi-layer structure of layers stacked in the third direction DR3. The first conductive layer 220 and the second conductive layer 240 may include conductive lines to define sensing electrodes having a mesh shape. The conductive lines may not overlap the opening PDL-OP and may overlap the pixel definition layer PDL.

The conductive layer having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (ITZO), or the like. In addition, the transparent conductive layer may include conductive polymer such as PEDOT, metal nanowire, graphene, or the like.

The conductive layer having the multi-layer structure may include metal layers. The metal layers may have a three-layer structure of titanium/aluminum/titanium. The conductive layer having the multi-layer structure may include at least one metal layer and at least one transparent conductive layer.

The sensing insulating layer 230 may be disposed between the first conductive layer 220 and the second conductive layer 240. The sensing insulating layer 230 may include an inorganic layer. The inorganic layer may include at least one of aluminum oxide, titanium oxide, silicon oxide, silicon nitride, silicon oxynitride, zirconium oxide, and hafnium oxide.

According to an embodiment, the sensing insulating layer 230 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The anti-reflective layer 300 may be disposed on the sensor layer 200. The anti-reflective layer 300 may include a light shielding pattern 310, a color filter 320, and a planarization layer 330.

The anti-reflective layer 300 may reduce a reflectance of the external light. The anti-reflective layer 300 may include the color filter 320. The color filter 320 may be provided in plural, and the color filters may be arranged in a predetermined way by taking into account colors of lights emitted from the pixels included in the display panel 100. According to an embodiment, the anti-reflective layer 300 may reduce the reflectance of the display module DM with respect to the external light using the color filter 320 without including a retarder and a polarizer. According to an embodiment, the anti-reflective layer 300 of the display module DM may not include a polarizing film or a polarizing layer.

A material for the light shielding pattern 310 should not be particularly limited as long as the material absorbs the light. The light shielding pattern 310 may be a layer having a black color. The light shielding pattern 310 may include a black coloring agent. The black coloring agent may include a black dye or a black pigment. The black coloring agent may include a metal material, such as carbon black, chromium, or an oxide thereof.

The light shielding pattern 310 may cover the second conductive layer 240 of the sensor layer 200. The light shielding pattern 310 may prevent the external light from being reflected from the second conductive layer 240. The light shielding pattern 310 may overlap a portion of the pixel definition layer PDL.

The light shielding pattern 310 may be provided with a division opening 310-OP2 defined therethrough. The division opening 310-OP2 may overlap the first electrode AE of the light emitting element LD. Each of the color filters 320 may overlap the first electrode AE of the light emitting element LD corresponding thereto. Each of the color filters 320 may cover a corresponding division opening 310-OP2. Each of the color filters 320 may be in contact with the light shielding pattern 310.

The planarization layer 330 may cover the light shielding pattern 310 and the color filters 320. The planarization layer 330 may include an organic material and may provide a flat surface thereon. According to an embodiment, the planarization layer 330 may be omitted.

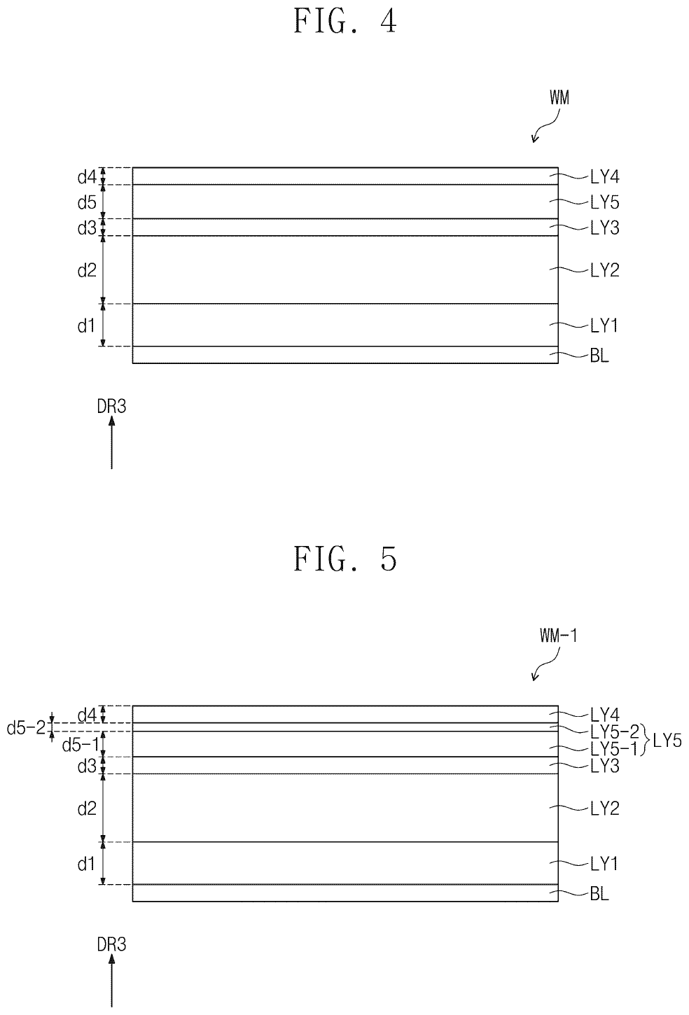

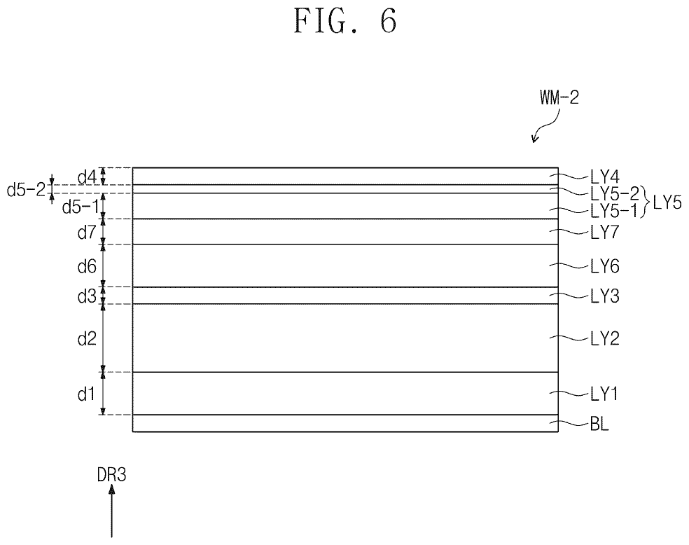

FIG. 4 is a cross-sectional view of the window WM according to an embodiment of the present disclosure. FIG. 5 is a cross-sectional view of a window WM-1 according to an embodiment of the present disclosure. FIG. 6 is a cross-sectional view of a window WM-2 according to an embodiment of the present disclosure.

Referring to FIG. 4, the window WM may include a base layer BL, a first layer LY1 disposed on the base layer BL, a second layer LY2 disposed on the first layer LY1, and a third layer LY3 disposed on the second layer LY2.

The base layer BL may include a transparent material. The base layer BL may include a glass substrate or a polymer film. The base layer BL may be a glass substrate that is chemically tempered. In the case where the base layer BL is the chemically tempered glass substrate, the base layer BL may have a high mechanical strength while having a thin thickness, and thus, the base layer BL may be used as a window of a foldable display device. In the case where the base layer BL is the polymer film, the base layer BL may include a polyimide (PI) film or a polyethylene terephthalate (PET) film. The base layer BL of the window WM may have a single-layer or multi-layer structure. As an example, the base layer BL may have a structure in which multiple polymer films are coupled with each other by an adhesive member or may have a structure in which the glass substrate is coupled with the polymer film by an adhesive. The base layer BL may include a flexible material. The base layer BL may have a thickness equal to or greater than about 1 μm and equal to or smaller than about 60 μm. Preferably, the thickness of the base layer BL may be about 20 μm. FIG. 4 shows the base layer BL having a rectangular shape when viewed in a cross-section as a representative example, however, it should not be limited thereto or thereby. According to an embodiment, the base layer BL may have a shape in which an edge of an upper surface of the base layer BL is rounded. In more detail, the edge of the upper surface of the base layer BL, which overlaps the bezel area BZA (refer to FIG. 1B), may be rounded.

The first layer LY1 may be disposed directly on the base layer BL. The second layer LY2 may be disposed directly on the first layer LY1, and the third layer LY3 may be disposed directly on the second layer LY2. Since the second layer LY2 having a relatively high refractive index is disposed on the first layer LY1 having a relatively low refractive index and the third layer LY3 having a relatively low refractive index is disposed on the second layer LY2, the window WM and the display device DD including the window WM may have a low-reflection property, a wear-resistant property, and a scratch-resistant property while being thinner than a conventional low-reflection window. As a result, a difficulty of the manufacturing process of the display device DD may be reduced.

Each of the first layer LY1, the second layer LY2, and the third layer LY3 may include a first compound. The first layer LY1, the second layer LY2, and the third layer LY3 may include the same material as each other. The first compound may include silicon nitride, silicon oxide, aluminum oxide, aluminum oxynitride, silicon oxynitride, silicon aluminum oxynitride, niobium oxide (Nb₂O₅), aluminum nitride (AlN), magnesium fluoride (MgF₂), magnesium oxide (MgO), titanium oxide (TiO₂), germanium oxide (GeO₂), magnesium aluminum oxide (MgAl₂O₄), barium fluoride (BaF₂), calcium fluoride (CaF₂), dysprosium fluoride (DyF₃), ytterbium fluoride (YbF₃), yttrium fluoride (YF₃), cerium fluoride (CeF₃), tantalum oxide (Ta₂O₅), hafnium oxide (HfO₂), zirconium oxide (ZrO₂₋), yttrium oxide (Y₂O₃), molybdenum oxide (MoO₃), and a diamond-like carbon. The ionic formula of the silicon nitride may be Si₃N₄. The ionic formula of the silicon oxide may be SiO₂. The ionic formula of the aluminum oxide may be Al₂O₃. The ionic formula of the aluminum oxynitride may be (AlN)ₓ(Al₂O₃)₁₋ₓ, and x is a real number equal to or greater than about 0.30 and equal to or smaller than about 0.37. The ionic formula of the silicon oxynitride may be Si_{b}O_{c}N_{d}, b is a real number equal to or greater than 1 and equal to or smaller than 3, c is a real number equal to or greater than 0 and equal to or smaller than 2, and d is a real number equal to or greater than 0 and equal to or smaller than 4. The “c” and the “d” are not equal to 0 at the same time. The silicon aluminum oxynitride may be represented as Si₆₋ₑAlₑOₑN₈₋ₑ, and “e” is a real number greater than 0 and equal to or smaller than 4.2. As an example, the first compound may include silicon nitride. The first compound may consist of silicon nitride. Each of the first layer LY1, the second layer LY2, and the third layer LY3 may include the first compound. As an example, each of the first layer LY1, the second layer LY2, and the third layer LY3 may include silicon nitride. The first layer LY1, the second layer LY2, and the third layer LY3, which include the first compound, may have high hardness, and thus, durability and the scratch-resistant property of the first layer LY1, the second layer LY2, and the third layer LY3 may be improved.

In the following descriptions, a packing density is defined as a ratio of an actual volume of a material to a total volume occupied by the material. In the following descriptions, the actual volume is defined as a volume obtained by subtracting a void volume from the total volume. The actual volume refers to a volume of space filled by matter. The void volume refers to a volume of empty space not occupied by matter. The packing density of each of the first layer LY1 and the third layer LY3 may be equal to or greater than about 75% or equal to or smaller than about 85% of the packing density of the second layer LY2. The first layer LY1 and the third layer LY3 may have substantially the same packing density. The packing density of each of the first layer LY1 and the third layer LY3 may be about 80% of the packing density of the second layer LY2. An increase of the packing density may mean that the void volume is relatively small and may allow an average distance between constituent materials to decrease, thereby causing more scattering and more refraction of light. Accordingly, the refractive index increases. In a case where two films have the same material, a film having a relatively high packing density may have a refractive index higher than a refractive index of the other film having a relatively low packing density. That is, each layer may have a packing density that is directly proportional to a refractive index thereof. Accordingly, the refractive index of the first layer LY1, the second layer LY2, and the third layer LY3 may be controlled by adjusting the packing density of the first layer LY1, the second layer LY2, and the third layer LY3. The first layer LY1, the second layer LY2, and the third layer LY3 of the window WM may have different refractive indices from each other while including the same first compound by using the relationship between the packing density and the refractive index. The refractive index of each of the first layer LY1 and the third layer LY3 may be equal to or greater than about 1.78 and equal to or smaller than about 1.87 at a wavelength of about 550 nm, and the refractive index of the second layer LY2 may be equal to or greater than about 1.98 and equal to or smaller than about 2.15 at the wavelength of about 550 nm. The first layer LY1 and the third layer LY3 may have substantially the same refractive index at the wavelength of about 550 nm. As an example, the refractive index of each of the first layer LY1 and the third layer LY3 may be about 1.82 at the wavelength of about 550 nm, and the refractive index of the second layer LY2 may be about 2.04 at the wavelength of about 550 nm. In a case where the refractive index of each of the first layer LY1 and the third layer LY3 is greater than about 1.87 at the wavelength of about 550 nm or the refractive index of the second layer LY2 is greater than about 2.15 at the wavelength of about 550 nm, a color difference may increase, and optical characteristics of the window WM may be deteriorated. In a case where the refractive index of each of the first layer LY1 and the third layer LY3 is smaller about 1.78 at the wavelength of about 550 nm, the packing density may be excessively low, and thus, the difficulty of the manufacturing process may increase.

The first layer LY1 may have a thickness d1 equal to or greater than about 78 nm and equal to or smaller than about 94 nm. The second layer LY2 may have a thickness d2 equal to or greater than about 120 nm and equal to or smaller than about 146 nm. The third layer LY3 may have a thickness d3 equal to or greater than about 15 nm and equal to or smaller than about 19 nm. As an example, the thickness d1 of the first layer LY1 may be about 85.48 nm, the thickness d2 of the second layer LY2 may be about 133.69 nm, and the thickness d3 of the third layer LY3 may be about 17.30 nm. In a case where the thickness d1 of the first layer LY1, the thickness d2 of the second layer LY2, and the thickness d3 of the third layer LY3 are greater than about 94 nm, about 146 nm, and about 19 nm, respectively, the color difference may increase, and thus, the optical characteristics of the window WM may be deteriorated. In a case where the thickness d1 of the first layer LY1, the thickness d2 of the second layer LY2, and the thickness d3 of the third layer LY3 are smaller than about 78 nm, about 120 nm, and about 15 nm, respectively, the durability and the scratch-resistant property of the window WM may be deteriorated. The first layer LY1, the second layer LY2, and the third layer LY3 may be deposited by a sputtering process.

The window WM may further include a fourth layer LY4 disposed above the third layer LY3. The fourth layer LY4 may include perfluoropolyether (PFPE). The fourth layer LY4 may be an anti-fingerprint coating layer. The fourth layer LY4 may have a refractive index equal to or greater than about 1.43 and equal to or smaller than about 1.52 at the wavelength of about 550 nm. As an example, the refractive index of the fourth layer LY4 may be about 1.48 at the wavelength of about 550 nm. An upper surface of the fourth layer LY4 may correspond to an outermost surface of the window WM. The fourth layer LY4 may have a thickness d4 equal to or greater than about 20 nm and equal to or smaller than about 30 nm. As an example, the thickness d4 of the fourth layer LY4 may be about 25 nm. In a case where the thickness d4 of the fourth layer LY4 is greater than about 30 nm, the color difference may increase, and the optical characteristics of the window WM may be deteriorated. In a case where the thickness d4 of the fourth layer LY4 is smaller than about 20 nm, anti-fingerprint characteristics may be deteriorated. The fourth layer LY4 may be deposited by an E-beam or a thermal evaporation deposition process.

The window WM may further include a fifth layer LY5 disposed between the third layer LY3 and the fourth layer LY4. The fifth layer LY5 may be disposed directly on the third layer LY3. The fifth layer LY5 may be disposed directly on a lower surface of the fourth layer LY4. The fifth layer LY5 may compensate for the optical characteristics of the window WM, and the fifth layer LY5 may improve the durability of the window WM by strengthening an adhesion between the fourth layer LY4 and the third layer LY3. The fifth layer LY5 may improve the scratch-resistant property of the window WM. The fifth layer LY5 may include silicon oxide. The fifth layer LY5 may have a refractive index equal to or greater than about 1.43 and equal to or smaller than about 1.52 at the wavelength of about 550 nm. In a case where the refractive index of the fifth layer LY5 is greater than about 1.52 at the wavelength of about 550 nm, the color difference may increase, and the optical characteristics of the window WM may be deteriorated. The fifth layer LY5 may have a thickness d5 equal to or greater than about 78 nm and equal to or smaller than about 94 nm. As an example, the thickness d5 of the fifth layer LY5 may be about 85.49 nm. In a case where the thickness d5 of the fifth layer LY5 is greater than about 94 nm, the color difference may increase, and the optical characteristics of the window WM may be deteriorated. In a case where the thickness d5 of the fifth layer LY5 is smaller than about 78 nm, the compensation for the optical characteristics may not be sufficient, and the fourth layer LY4 and the third layer LY3 may not be brought into close contact with each other. As a result, the durability of the window WM may be deteriorated, and the scratch-resistant property of the window WM may be deteriorated. The fifth layer LY5 may be deposited by a sputtering process or a thermal evaporation deposition process.

Different from the window WM shown in FIG. 4, the window WM-1 shown in FIG. 5 may include a fifth layer LY5 configured to include a fifth-first layer LY5-1 and a fifth-second layer LY5-2. In FIG. 5, descriptions about the window WM-1 will be focused on different features from those of the window WM shown in FIG. 4.

The fifth layer LY5 of the window WM-1 may include the fifth-first layer LY5-1 disposed on a third layer LY3 and the fifth-second layer LY5-2 disposed between the fifth-first layer LY5-1 and a fourth layer LY4. The fifth-first layer LY5-1 may be disposed directly on the third layer LY3. The fifth-second layer LY5-2 may be disposed directly on the fifth-first layer LY5-1. The fifth-second layer LY5-2 may be disposed directly on a lower surface of the fourth layer LY4. The fifth-second layer LY5-2 may improve a durability of the window WM-1 by strengthening an adhesion between the fourth layer LY4 and the fifth-first layer LY5-1. The fifth-first layer LY5-1 and the fifth-second layer LY5-2 may include silicon oxide. The fifth-first layer LY5-1 may have a planar structure, and the fifth-second layer LY5-2 may have a columnar structure. The planar structure refers to a case where a crystal structure of SiO₂ is an alpha quartz structure. The columnar structure refers to a case where the crystal structure of SiO₂ is a beta tridymite structure. The fifth-first layer LY5-1 may be deposited by a sputtering process. The fifth-second layer LY5-2 may be deposited by a thermal evaporation deposition process. The fifth-first layer LY5-1 may have a thickness d5-1 equal to or greater than about 58 nm and equal to or smaller than about 72 nm. The fifth-second layer LY5-2 may have a thickness d5-2 equal to or greater than about 8 nm and equal to or smaller than about 25 nm. In a case where the thickness d5-1 of the fifth-first layer LY5-1 is greater than about 72 nm or the thickness d5-2 of the fifth-second layer LY5-2 is greater than about 25 nm, the color difference may increase, and the optical characteristics of the window WM-1 may be deteriorated. In a case where the thickness d5-1 of the fifth-first layer LY5-1 is smaller than about 58 nm or the thickness d5-2 of the fifth-second layer LY5-2 is smaller than about 8 nm, the compensation for the optical characteristics may not be sufficient, and the fourth layer LY4 and the third layer LY3 may not be brought into close contact with each other. As a result, the durability of the window WM-1 may be deteriorated, and the scratch-resistant property of the window WM-1 may be deteriorated.

Different from the window WM-1 shown in FIG. 5, the window WM-2 shown in FIG. 6 may further include a sixth layer LY6 and a seventh layer LY7. In FIG. 6, descriptions about the window WM-2 will be focused on different features from those of the windows WM and WM-1 shown in FIGS. 4 and 5.

The window WM-2 may include the sixth layer LY6. The sixth layer LY6 may be disposed on a third layer LY3. The sixth layer LY6 may be disposed directly on the third layer LY3. The sixth layer LY6 may include a first compound. The sixth layer LY6 may include substantially the same compound as a first layer LY1, a second layer LY2, or the third layer LY3. As an example, the sixth layer LY6 may include silicon nitride. The sixth layer LY6 may consist of the first compound. The sixth layer LY6 may consist of silicon nitride. The sixth layer LY6 may have substantially the same packing density as a packing density of the second layer LY2. The sixth layer LY6 may have a refractive index equal to or greater than about 1.98 and equal to or smaller than about 2.15 at a wavelength of about 550 nm. The sixth layer LY6 and the second layer LY2 may have the same refractive index as each other at the wavelength of about 550 nm. As an example, the refractive index of the sixth layer LY6 may be about 2.04 at the wavelength of about 550 nm. In a case where the refractive index of the sixth layer LY6 is greater than about 2.15 at the wavelength of about 550 nm, a color difference may increase, and thus optical characteristics of the window WM-2 may be deteriorated. In a case where the refractive index of the sixth layer LY6 is smaller than about 1.98 at the wavelength of about 550 nm, the packing density may be excessively low, and thus, the difficulty of the manufacturing process may increase. The sixth layer LY6 may be disposed directly on the third layer LY3. The second layer LY2 having a relatively high refractive index may be disposed on the first layer LY1 having a relatively low refractive index, the third layer LY3 having a relatively low refractive index may be disposed on the second layer LY2, and the sixth layer LY6 having a relatively high refractive index may be disposed on the third layer LY3. Accordingly, the window WM-2 and the display device DD including the window WM-2 may have a low-reflection property, a wear-resistant property, and a scratch-resistant property while being thinner than a conventional low-reflection window. As a result, a difficulty of the manufacturing process of the display device DD may be reduced. The sixth layer LY6 may have a thickness equal to or greater than about 146 nm. As an example, the thickness of the sixth layer LY6 may be about 133.69 nm. In a case where the thickness of the sixth layer LY6 is greater than about 146 nm, the color difference may increase, and the optical characteristics of the window WM-2 may be deteriorated. In a case where the thickness of the sixth layer LY6 is smaller than about 120 nm, the durability and the scratch-resistant property of the window WM-2 may be deteriorated. The sixth layer LY6 may be deposited by a sputtering process.

The window WM-2 may include the seventh layer LY7. The seventh layer LY7 may be disposed on the sixth layer LY6. The seventh layer LY7 may be disposed directly on the sixth layer LY6. The seventh layer LY7 may be disposed directly on a lower surface of a fifth layer LY5. The seventh layer LY7 may be disposed directly on a lower surface of a fifth-first layer LY5-1. The seventh layer LY7 may include the first compound. The seventh layer LY7 may include the same compound as the first layer LY1, the second layer LY2, or the third layer LY3. As an example, the seventh layer LY7 may include silicon nitride. The seventh layer LY7 may consist of the first compound. The seventh layer LY7 may consist of silicon nitride. The seventh layer LY7 may have substantially the same packing density as a packing density of the first layer LY1 or the third layer LY3. The seventh layer LY7 may have a refractive index equal to or greater than about 1.78 and equal to or smaller than about 1.87 at the wavelength of about 550 nm. The seventh layer LY7, the first layer LY1, and the third layer LY3 may have substantially the same refractive index as each other at the wavelength of about 550 nm. As an example, the refractive index of the seventh layer LY7 may be about 1.82 at the wavelength of about 550 nm. In a case where the refractive index of the seventh layer LY7 is greater than about 1.87 at the wavelength of about 550 nm, the color difference may increase, and thus the optical characteristics of the window WM-2 may be deteriorated. In a case where the refractive index of the seventh layer LY7 is smaller than about 1.78 at the wavelength of about 550 nm, the packing density may be excessively low, and thus, the difficulty of the manufacturing process may increase. The seventh layer LY7 may be disposed directly on the sixth layer LY6. The second layer LY2 having the relatively high refractive index may be disposed on the first layer LY1 having the relatively low refractive index, the third layer LY3 having the relatively low refractive index may be disposed on the second layer LY2, the sixth layer LY6 having the relatively high refractive index may be disposed on the third layer LY3, and the seventh layer LY7 having a relatively low refractive index may be disposed on the sixth layer LY6. Accordingly, the window WM-2 and the display device DD including the window WM-2 may have the low-reflection property, the wear-resistant property, and the scratch-resistant property while being thinner than a conventional low-reflection window. As a result, a difficulty of the manufacturing process of the display device DD may be reduced. The seventh layer LY7 may have a thickness equal to or greater than about 15 nm and equal to or smaller than about 19 nm. As an example, the thickness of the seventh layer LY7 may be about 17.30 nm. In a case where the thickness of the seventh layer LY7 is greater than about 19 nm, the color difference may increase, and the optical characteristics of the window WM-2 may be deteriorated. In a case where the thickness of the seventh layer LY7 is smaller than about 15 nm, the durability and the scratch-resistant property of the window WM-2 may be deteriorated. The seventh layer LY7 may be deposited by a sputtering process.

Hereinafter, the results of evaluating the optical characteristics, the durability, and the scratch-resistant property of the window in terms of the reflectance, the transmittance, the color difference, and the hardness will be described in detail.

The window according to embodiment example 1 has a structure in which the first layer is disposed on a member containing glass, the second layer is disposed on the first layer, the third layer disposed on the second layer, the fifth layer is disposed on the third layer, and the fourth layer is disposed on the fifth layer. The first layer included in the window of embodiment example 1 includes Si₃N₄ and has the thickness of about 85.48 nm. The second layer included in the window of embodiment example 1 includes Si₃N₄ and has the thickness of about 133.69 nm. The third layer included in the window of embodiment example 1 includes Si₃N₄ and has the thickness of about 17.30 nm. The first layer, the second layer, and the third layer are deposited by the sputtering method, and the first and third layers have the packing density corresponding to about 75% of the packing density of the second layer. The refractive index of the first layer and the third layer is measured to be about 1.78 at the wavelength of about 550 nm, and the refractive index of the second layer is measured to be about 2.04. The fifth layer includes SiO₂ and has the thickness of about 85.49 nm. The fifth layer is deposited by the thermal evaporation method. The refractive index of the fifth layer is measured to be about 1.48 at the wavelength of about 550 nm. The fourth layer may include perfluoropolyether (PEFE) and has the thickness of about 25 nm. The fourth layer is deposited by the thermal evaporation method. The window according to embodiment example 2 is formed identically to the window of embodiment example 1 except that the first layer and the third layer have the packing density corresponding to about 80% of the packing density of the second layer and have the refractive index of about 1.82. The window according to embodiment example 3 is formed identically to the window of embodiment example 1 except that the first layer and the third layer have the packing density corresponding to about 85% of the packing density of the second layer and have the refractive index of about 1.87. A window according to comparative example 1 is formed identically to the window of embodiment example 1 except that a first layer and a third layer have a packing density corresponding to about 70% of a packing density of a second layer and have a refractive index of about 1.73. A window according to comparative example 2 is formed identically to the window of embodiment example 1 except that a first layer and a third layer have a packing density corresponding to about 90% of a packing density of a second layer and have a refractive index of about 2.00.

In order to evaluate the optical characteristics according to the refractive index of the first layer, the second layer, and the third layer of the window, the reflectance, the transmittance, and the color difference are measured by adjusting the packing density and the refractive index of the first layer, the second layer, and the third layer based on the wavelength of about 550 nm, and the results are shown in Table 1 below. As the reflectance becomes lower and the transmittance becomes higher, the low-reflection characteristics are improved, and when the color difference is equal to or smaller than about 2.0, it is considered that the color reproducibility is excellent. The color difference is the resulting value of ((ΔL*)²+(a*₂-a*₁)²+(b*₂-b*₁)²)^{0.5} when viewed at an incident illumination angle ranging from about 0 degrees to about 60 degrees with respect to a normal incidence under an International Commission on Illumination (CIE) illuminant selected from the group consisting of A series illuminant, B series illuminant, C series illuminant, D series illuminant, and F series illuminant. L denotes brightness in the CIE color coordinate system, a*₁ and b*₁ denote color coordinates when viewed from the normal incidence, and a*₂ and b*₂ denote color coordinates when viewed from the incident illumination angle.

TABLE 1

| | Embodiment | Embodiment | Embodiment | comparative | Comparative |
|---|---|---|---|---|---|
| | example 1 | example 2 | example 3 | example 1 | example 2 |
| reflectance | 4.72 | 4.71 | 4.61 | 4.68 | 6.03 |
| (%) | | | | | |
| transmittance | 95.19 | 95.23 | 95.30 | 5.07 | 93.91 |
| (%) | | | | | |
| L* | 26.50 | 26.66 | 26.90 | 26.69 | 28.78 |
| a* | −0.90 | −0.39 | 0.10 | −0.97 | 2.89 |
| b* | −1.80 | −1.76 | −1.63 | −1.62 | −0.54 |
| color | 2.02 | 1.80 | 1.64 | 1.89 | 2.94 |
| difference | | | | | |

Referring to Table 1, embodiment example 1 to embodiment example 3 have low reflectance compared with comparative example 2 and have excellent optical characteristics as a low-reflection layer. In addition, comparative example 2 has a color difference that significantly exceeds two (2), so the color reproducibility of comparative example 2 is not excellent, but embodiment example 1 to embodiment example 3 have the color difference similar to or less than 2, and thus, the color reproducibility of embodiment example 1 to embodiment example 3 is excellent. Comparative example 1 does not show significant differences in reflectance and color difference compared with embodiment example 1 to embodiment example 3. However, comparative example 1 is not suitable for mass production since the difficulty of the manufacturing process increases to set the refractive index of the first to third layers to about 1.73 by adjusting the packing density.

In order to evaluate the optical characteristics according to the thickness of the first layer, the second layer, and the third layer of the window, the reflectance, the transmittance, and the color difference are measured by adjusting the thickness of the first layer, the second layer, and the third layer based on the wavelength of about 550 nm, and the results are shown in Table 2 below. The window of embodiment example 2 is the same as the window of embodiment example 2 shown in Table 1. The window of comparative example 4 is the same as the window of embodiment example 2 except that first, second, third, and fifth layers have thicknesses of about 70 nm, about 115 nm, about 10 nm, and about 70 nm, respectively. The window of comparative example 5 is the same as the window of embodiment example 2 except that first, second, third, and fifth layers have thicknesses of about 100 nm, about 152 nm, about 30 nm, and about 100 nm, respectively. Descriptions about reflectance, transmittance, color difference, L, a*₁, b*₁, a*₂, and b*₂ are substantially the same as those with reference to Table 1

TABLE 2

| | comparative | embodiment | comparative |
|---|---|---|---|
| | example 4 | example 2 | example 5 |
| reflectance (%) | 5.73 | 4.71 | 7.67 |
| transmittance | 94.20 | 95.23 | 92.28 |
| (%) | | | |
| L* | 28.84 | 26.66 | 30.77 |
| a* | 10.93 | −0.39 | 3.40 |
| b* | −18.73 | −1.76 | 7.17 |
| color difference | 21.68 | 1.80 | 7.93 |

Referring to Table 2, embodiment example 2 has low reflectance compared with comparative examples 4 and 5 and has excellent optical characteristics as the low-reflection layer. In addition, comparative examples 4 and 5 have the color difference that significantly exceeds two (2), so the color reproducibility of comparative examples 4 and 5 is not excellent, but embodiment example 2 has the color difference less than 2, and thus, the color reproducibility of embodiment example 2 is excellent.

In order to evaluate the durability and the scratch-resistant property of the window, a hardness Gpa of the window of embodiment example 2 (shown in Tables 1 and 2) and a hardness Gpa of the window of comparative example 6 are measured through a Berkovich indenter hardness (Gpa) test based on an indentation depth of about 100 nm and about 150 nm, and the results are shown in Table 3 below. The window of comparative example 6 includes a member containing glass and does not include the above-described first to fifth layers.

TABLE 3

| | embodiment | comparative |
|---|---|---|
| | example 2 | example 6 |
| indentation depth | 100/11.5 | 100/7 |
| (nm)/hardness (Gpa) | | |
| indentation depth | 150/12.2 | 100/9 |
| (nm)/hardness (Gpa) | | |

Referring to Table 3, embodiment example 2 has excellent hardness at both indentation depths compared with comparative example 6. Accordingly, embodiment example 2 has improved durability and scratch-resistant property compared with comparative example 6.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A window comprising:
a base layer;
a first layer disposed on the base layer;
a second layer disposed on the first layer; and
a third layer disposed on the second layer, wherein each of the first, second, and third layers comprise a first compound, and when a ratio of an actual volume of a material to a total volume occupied by the material is defined as a packing density and the actual volume is defined by subtracting a void volume from the total volume, each of the first and third layers has a packing density of between about 75% to about 85% of a packing density of the second layer.

2. The window of claim 1, wherein the first compound comprises one of silicon nitride, silicon oxide, aluminum oxide, aluminum oxynitride, silicon oxynitride, silicon aluminum oxynitride, niobium oxide, aluminum nitride, magnesium fluoride, magnesium oxide, titanium oxide, germanium oxide, magnesium aluminum oxide, barium fluoride, calcium fluoride, dysprosium fluoride, ytterbium fluoride, yttrium fluoride, cerium fluoride, tantalum oxide, hafnium oxide, zirconium oxide, yttrium oxide, molybdenum oxide, and a diamond-like carbon.

3. The window of claim 1, wherein the first compound comprises silicon nitride.

4. The window of claim 1, wherein each of the first, second, and third layers consists of the first compound.

5. The window of claim 1, wherein the packing density of the first layer is substantially equal to the packing density of the third layer.

6. The window of claim 1, wherein the packing density of each of the first and third layers is about 80% of the packing density of the second layer.

7. The window of claim 1, wherein each of the first and third layers has a refractive index equal to or greater than about 1.78 and equal to or smaller than about 1.87 at a wavelength of about 550 nm, and the second layer has a refractive index equal to or greater than about 1.98 and equal to or smaller than about 2.15 at the wavelength of about 550 nm.

8. The window of claim 1, wherein the first and third layers have a same refractive index as each other at a wavelength of about 550 nm.

9. The window of claim 1, wherein the second layer is disposed directly on the first layer, and the third layer is disposed directly on the second layer.

10. The window of claim 1, wherein the first layer has a thickness equal to or greater than about 78 nm and equal to or smaller than about 94 nm, the second layer has a thickness equal to or greater than about 120 nm and equal to or smaller than about 146 nm, and the third layer has a thickness equal to or greater than about 15 nm and equal to or smaller than about 19 nm.

11. The window of claim 1, further comprising a fourth layer disposed on the third layer and comprising perfluoropolyether (PFPE).

12. The window of claim 11, wherein the fourth layer has a thickness equal to or greater than about 20 nm and equal to or smaller than about 30 nm.

13. The window of claim 11, further comprising a fifth layer disposed between the third layer and the fourth layer and having a refractive index equal to or greater than about 1.43 and equal to or smaller than about 1.52 at a wavelength of about 550 nm.

14. The window of claim 13, wherein the fifth layer comprises:
a fifth-first layer disposed on the third layer; and
a fifth-second layer disposed between the fifth-first layer and the fourth layer.

15. The window of claim 14, wherein the fifth-first layer has a planar structure, and the fifth-second layer has a columnar structure.

16. The window of claim 1, further comprising a sixth layer disposed on the third layer, comprising the first compound, and having a substantially same packing density as the packing density of the second layer.

17. A display device comprising:
a display module; and
a window disposed on the display module, the window comprising:
a first layer disposed on the display module;
a second layer disposed on the first layer; and
a third layer disposed on the second layer, wherein each of the first, second, and third layers comprise a same compound, and when a ratio of an actual volume of a material to a total volume occupied by the material is defined as a packing density and the actual volume is defined by subtracting a void volume from the total volume, each of the first and third layers has a packing density of between about 75% to about 85% of a packing density of the second layer.

18. The display device of claim 17, wherein the display module comprises:
a base substrate;
a circuit layer disposed on the base substrate;
a light emitting element layer comprising a light emitting element and disposed on the circuit layer; and
an anti-reflective layer comprising a color filter overlapping the light emitting element and disposed on the light emitting element layer.

19. The display device of claim 17, further comprising a fourth layer disposed on the third layer and comprising perfluoropolyether (PFPE).

20. The display device of claim 19, wherein an upper surface of the fourth layer defines an outermost surface of the window.
